(19) United States
(12) Patent Application Publication
(10) Pub. No.: US 2005/0006688 A1
(43) Pub. Date: Jan. 13, 2005

(54) Arrangement comprising a capacitor

(76) Inventor: Jose Solo De Zaldivar, Waedenswill (CH)

Correspondence Address: Philips Electronics North America Corporation;Intellectual Property Standards, 1109 McKay Drive, M S41 SJ, San Jose, CA, 95131, US

(21) Appl. No.: 10/497,805

(22) PCT Filed: Dec. 2, 2002
(86) PCT No.: PCT/IB02/05111

(30) Foreign Application Priority Data
Dec. 4, 2001 (DE) 101 59 466.6

(51) Int. Cl. H01L 27/108

(52) U.S. Cl. 257/306

(57) ABSTRACT

An arrangement comprising a substrate, a capacitor, an interconnection layer and a contact structure, wherein the capacitor comprises a first electrode (6) and a second electrode (9) and also an interposed dielectric (8), the contact structure comprises a UBM (under-bump metallization) layer (9) and a bump contact (10), the interconnection layer (6) forms the first electrode of the capacitor, and the UBM layer (9) forms the second electrode of the capacitor.

The invention relates to an arrangement comprising a substrate, a capacitor, an interconnection layer, and a contact structure, wherein the capacitor comprises a first electrode and a second electrode and also an interposed dielectric, and the contact structure comprises a UBM (under-bump metallization) layer and a bump contact. The invention also relates to a display device.

An integrated circuit comprises a number of semiconductor elements that are normally produced in a single-crystal semiconductor wafer. A thin dielectric layer is deposited or grown on the surface of the semiconductor wafer and on regions having polycrystalline semiconductor material. A relatively thick dielectric layer is deposited on the semiconductor components. Contact holes or vias providing access to the terminal ends of the semiconductor components are etched through said thick dielectric layer. The various semiconductor elements are electrically interconnected by a complex pattern of strip conductors situated on the thick dielectric layer. The strip conductors, also called interconnection layers, make contact with the terminal ends of the semiconductor components through the vias in the thick dielectric layer. After these contacts have been established, a protective layer is deposited on this connecting strip conductor pattern. Contact vias in the protective layer provide access to square constituents of the connecting pattern, the so-called contact pads (contact lands). Electrical connections are made to the integrated circuits via said contact pads. For making electrical contacts, so-called bump contacts are used, which are composed of a first electrically conducting layer and of a second, markedly thicker electrically conducting layer. The first electrically conducting layer is also described as a UBM (under-bump metallization) layer and comprises, for example, TiW/Au. The second electrically conducting layer is the actual bump contact and comprises, for example, gold, which is applied by means of electroplating.

An integrated circuit may be used, for example, to transfer information data and power to a device for generating a visual display of the information. For this purpose, an integrated circuit comprises further components such as, for example, capacitors. Such a capacitor is generally formed from two electrodes and a dielectric layer. Normally, the capacitors are applied directly to the semiconducting material. A disadvantage, however, is that the capacitors occupy an appreciable area of the semiconducting substrate and thus increase the production cost of the semiconductor component.

U.S. Pat. No. 5,741,721 discloses, for example, a capacitor that is applied to a chip comprising an integrated circuit.

It is an object of the invention to provide an arrangement comprising a capacitor, an interconnection layer, and a contact structure that is inexpensive and easy to produce.

Said object is achieved by an arrangement comprising a substrate, a capacitor, an interconnection layer, and a contact structure, wherein the capacitor comprises a first electrode and a second electrode and also an interposed dielectric, the contact structure comprises a UBM (under-bump metallization) layer and a bump contact, the interconnection layer forms the first electrode of the capacitor, and the UBM layer forms the second electrode of the capacitor.

This structure of the arrangement has the advantage that the capacitor can be produced by standard processes for manufacturing integrated circuits and contact structures with only one additional material deposition step and two additional mask steps. Consequently, the arrangement according to the invention can be produced inexpensively and easily.

The further advantageous embodiments as defined in the dependent claims 2 to 4 render possible an easy and inexpensive manufacture of arrangements comprising complex functions, for example circuits for driving display devices. Furthermore, the invention relates to a display device that comprises an arrangement comprising a substrate, a capacitor, an interconnection layer, and a contact structure, wherein the capacitor comprises a first electrode and a second electrode and also an interposed dielectric, the contact structure comprises a UBM (under-bump metallization) layer and a bump contact, the interconnection layer forms the first electrode of the capacitor, and the UBM layer forms the second electrode of the capacitor.

These and other aspects of the invention are apparent from and will be elucidated with reference to a possible embodiment described hereinafter.

In the drawings:

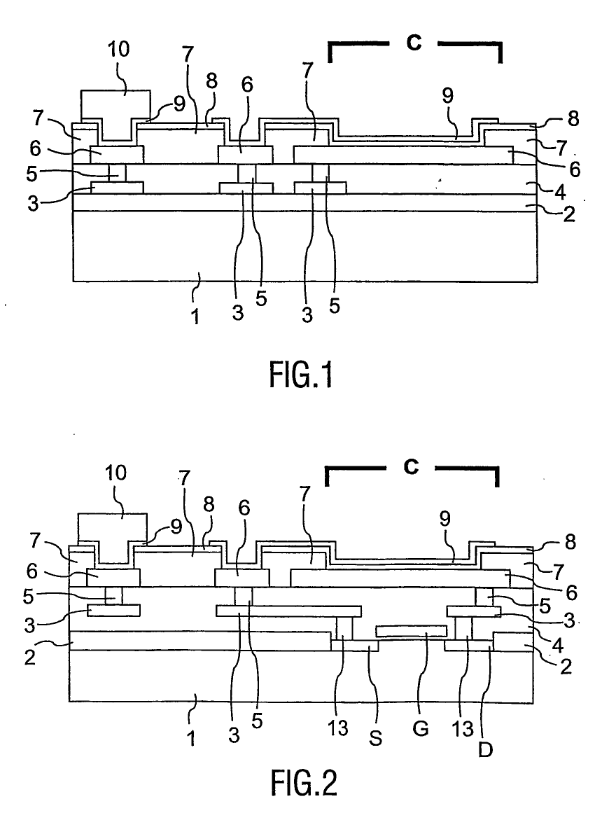

FIG. 1 and FIG. 2 each show a diagrammatic cross-section through a possible arrangement, and

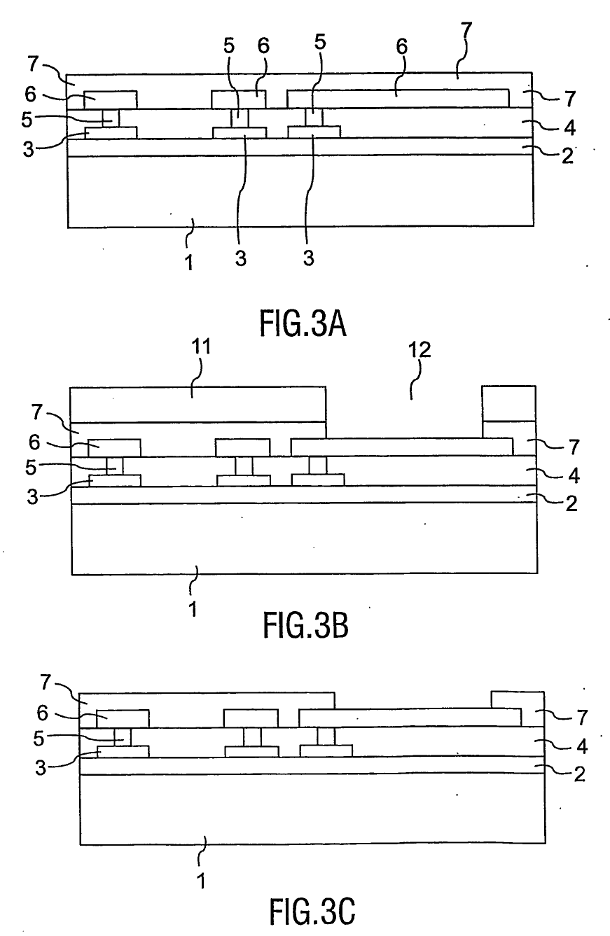

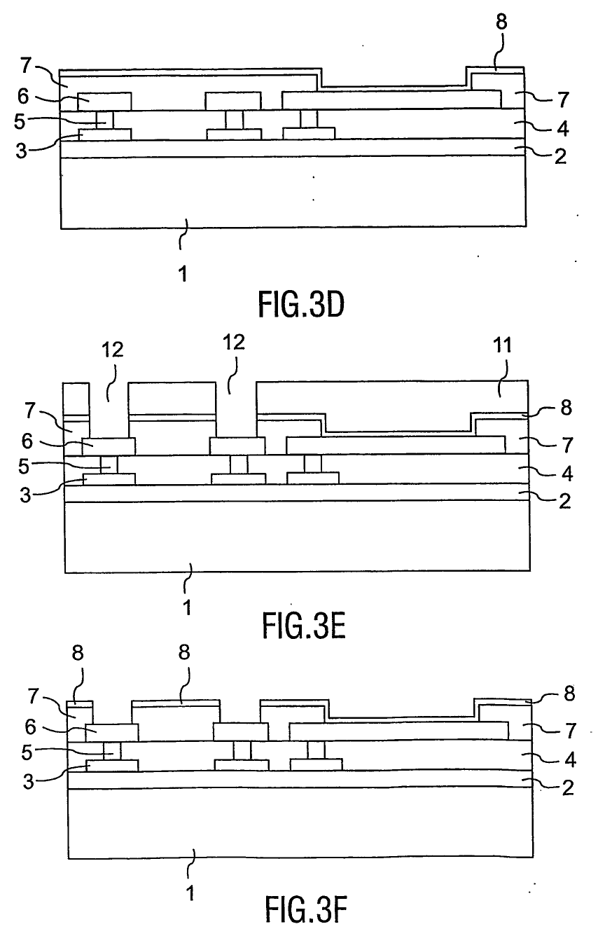

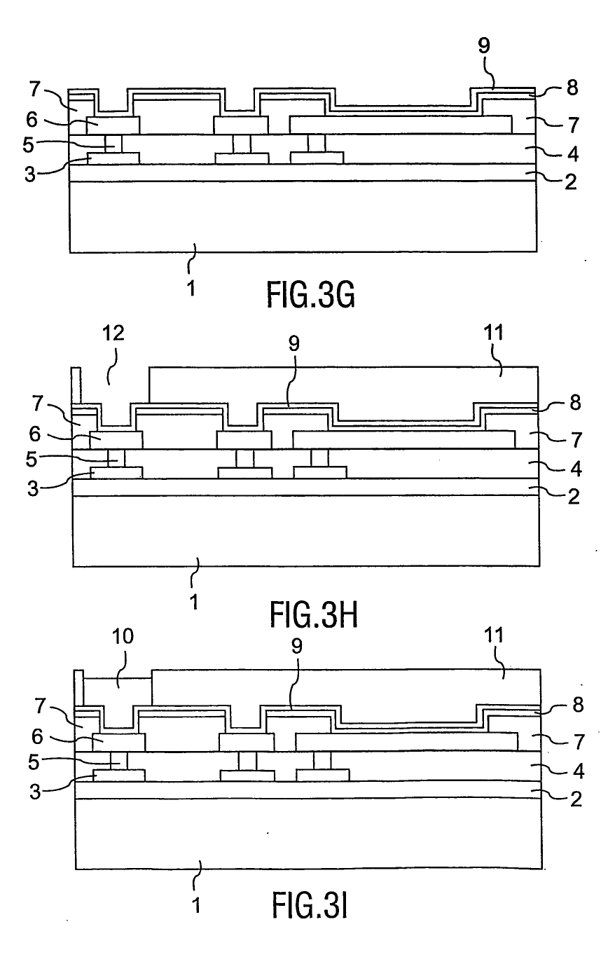

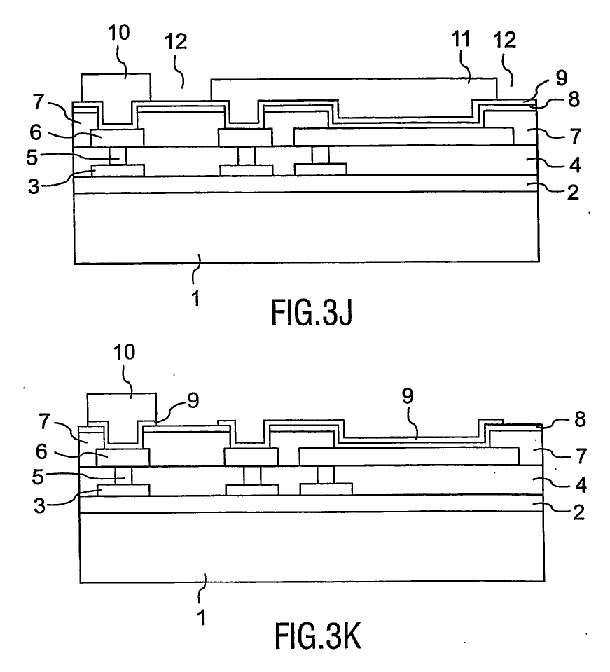

FIG. 3 shows a flowchart for the production steps of a possible arrangement.

A display device, for example a liquid-crystal picture screen, comprises at least one arrangement, for example an integrated circuit, for driving it. Said arrangement comprises, in addition to active components, also further components such as, for example, capacitors.

FIG. 1 is a diagrammatic cross section through an arrangement comprising two interconnection layers, a capacitor, and a contact structure. Deposited on a substrate 1 are different material layers that form a capacitor C and two interconnection layers. The purpose of the interconnection layers is to connect the capacitor to other components of the arrangement and also to interconnect said components. Depending on the use of the arrangement and the method of production, the substrate 1 may contain an insulating material, a semiconducting material, a conducting material or a composite structure of two or more layers.

If the substrate 1 comprises an insulating material, it may be preferable for the insulating material to be a ceramic material such as, for example, Al₂O₃ or AlN.

If the substrate 1 comprises a semiconducting material, it may be preferable for the semiconducting material to comprise silicon, gallium arsenide, indium phosphide, gallium-aluminum arsenide, or germanium. It may be advantageous for said materials to be doped with boron, arsenic, antimony, phosphorus, or a combination of said dopants. One or more active component such as, for example, diodes or transistors may be situated in the substrate 1. The active components may advantageously form an integrated circuit.

If the substrate 1 comprises a conducting material, it may be preferable for the conducting material to be a heat-resistant metal, for example, tungsten or molybdenum.

If the substrate 1 comprises a composite structure of two or more layers, it may be preferable for said composite structure to be produced using LTCC (low-temperature co-fired ceramics) technology. One or more passive components such as, for example, resistors, capacitors, inductances, or strip conductors may additionally be integrated in the LTCC composite structure. The passive components may advantageously form an integrated circuit.

Alternatively, the composite structure may comprise two or more layers of a semiconducting material, each layer being of different thickness or being doped with different dopants. In this embodiment, the individual layers may again comprise one or more active components such as, for example, diodes or transistors. The active components may advantageously form an integrated circuit. It may also be advantageous for the composite structure of two or more layers to comprise a layer of an insulating material and a layer of a conducting or semiconducting material.

Applied to the substrate 1 is preferably an insulating layer 2, which may comprise, for example, SiO₂. It may be advantageous for the insulating layer 2 to comprise SiO₂ doped with, for example, boron, arsenic, antimony, phosphorus, or a combination of said dopants. A first interconnection layer 3 is applied in a patterned manner to the insulating layer 2. A first dielectric layer 4 is situated on the first interconnection layer 3 and on those regions of the insulating layer 2 that are not covered by the first interconnection layer 3. The first dielectric layer 4 comprises, for example, SiO₂, Si₃N₄ or SiₓO_{y}N_{z} (0≦x≦1, 0≦y≦1, 0≦Z≦1). A second interconnection layer 6 is deposited in a patterned manner on the first dielectric layer 4. The first interconnection layer 3 is electrically connected to the second interconnection layer 6 via electrically conducting contact vias 5 in a few regions. The first interconnection layer 3, the second interconnection layer 6, and the contact vias 5 comprise, for example, Ti/TiN/Al (Cu). A protective layer 7 is deposited on the second interconnection layer 6 and on those regions of the first dielectric layer 4 that are not covered by the second interconnection layer 6. The protective layer 7 may be an inorganic material such as, for example, SiO₂, Si₃N₄, or SiₓO_{y}N_{z} (0≦x≦1, 0≦y≦1, 0≦z≦1), an organic material such as, for example, polyamide or polycyclobenzobutene, or a combination of inorganic and organic materials. The protective layer 7 is interrupted in a few regions in such a way that the regions of the second interconnection layer 6 are not covered by the protection layer 7. A second dielectric layer 8, which preferably comprises an oxide, a nitride or an oxynitride, is deposited on that region of the second interconnection layer 6 where a capacitor is later to be situated and on the protective layer 7. Preferably, the second dielectric layer 8 comprises SiO₂, Si₃N₄, or SiₓO_{y}N_{z} (0≦x≦1, 0≦y≦1, 0≦z≦1). Those regions of the second interconnection layer 6 that are covered by the second dielectric layer 8 function as a first electrode of the capacitor in this region. Those regions of the second dielectric layer 8 that are deposited directly on the second interconnection layer 6 function as the dielectric of the capacitor in this region. A UBM (under-bump metallization) layer 9 that preferably contains Au/TiW is deposited on the second dielectric layer 8 and also on those regions of the second interconnection layer 6 that are not covered by the second dielectric layer 8. In the regions where a capacitor is to be situated, the UBM layer 9 functions as second electrode of the capacitor. A bump contact 10, which preferably comprises Au and is deposited, for example, by means of electroplating on the UBM layer 9, forms a contact structure together with the UBM layer 9 in this region for making electrical contact with the capacitor and/or the components or integrated circuits situated in the substrate 1. The connecting structure is in electrical contact with the second interconnection layer 6.

Alternatively, the UBM layer 9 may be patterned in such a way that it additionally functions as a connection conductor and interconnects, for example, the capacitor and the second interconnection layer 6 or a plurality of contact structures.

Alternatively, the various material layers, for example the first interconnection layer 3 and the second interconnection layer 6, may be patterned in such a way that they form one or more further components of the arrangement. In an arrangement for driving a display device, such a component may be, for example, a column and row decoder for an array of non-volatile semiconductor memories, an input/output unit (I/O unit), a SRAM (static random access memory) cell, a ROM (read-only memory) cell, or a logic component. An electrical connection of said components, for example, to one another or to the capacitor or to a connection structure may be advantageously made via the UBM layer 9.

Components such as, for example, integrated circuits, active components, or passive components situated in the substrate 1 may be connected to the first interconnection layer 3 via electrically conducting vias (not shown) situated in the insulating layer 2.

The capacitor may function, for example, as a “charge pump” capacitor or as a decoupling capacitor.

FIG. 2 is a diagrammatic cross-section through an arrangement comprising two interconnection layers, a capacitor, and a contact structure that are situated above a transistor. In this embodiment, the substrate 1 comprises a semiconducting material. Situated in the substrate 1 are two semiconductor regions, the source region S, and the drain region D of the transistor. The insulating layer 2 is preferably an SiO₂ field oxide layer. The gate G of the transistor is situated in the first dielectric layer 4, which preferably comprises SiO₂. The gate G comprises, for example, n-type or p-type polysilicon. The first interconnection layer 3 is connected to the semiconductor regions S, D in the substrate 1 via electrically conducting vias 13.

FIG. 3 shows a method of manufacturing an arrangement according to the invention. To manufacture an arrangement according to the invention, for example, a wafer as shown in FIG. 3A comprising a substrate 1, an insulating layer 2, a first interconnection layer 3 which is connected by means of contact vias 5 to a second interconnection layer 6, a first dielectric layer 4 that is situated between the first interconnection layer 3 and the second interconnection layer 6, and a protective layer 7 is first produced by means of known processes. Situated in the substrate 1, which comprises a semiconducting material, are active components in the form of an integrated circuit. The integrated circuit is connected to the first interconnection layer 3 by electrically conducting vias (not shown) in the insulating layer 2.

On said wafer, a photoresist 11 is first deposited, as shown in FIG. 3B, and is patterned in such a way that those regions of the second interconnection layer 6 on which a capacitor is later to be situated are not covered by the photoresist 11. For this purpose, a hole 12 is created, for example by means of etching, through the layer of photoresist 11 and the protective layer 7 at this point. The photoresist 11 is then removed as shown in FIG. 3C.

A second dielectric layer 8 is deposited on the protective layer 7 and the exposed regions of the second interconnection layer 6 (FIG. 3D).

A photoresist 11 is deposited on the second dielectric layer 8 and patterned in such a way that those regions of the second interconnection layer 6 are exposed where an electrical contact is later to be made to the contact structure or the capacitor. For this purpose, a hole 12 is made in each of these regions, for example by means of etching, through the layer of photoresist 11, the second dielectric layer 8, and the protective layer 7 (FIG. 3E). The photoresist is then removed, as shown in FIG. 3F.

A UBM layer 9 is deposited on the second dielectric layer 8 and the exposed regions of the second interconnection layer 6 (FIG. 3G).

A photoresist 11 is deposited on the UBM layer 9 and patterned in such a way that those regions of the UBM layer 9 are exposed where there is to be a contact structure later. (FIG. 3H). The bump contact 10 is then made, for example by means of electroplating (FIG. 3I).

To pattern the UBM layer 9 further, the photoresist 11 is patterned again by creating a hole 12 in each of those regions where no UBM layer 9 is to be situated in the finished arrangement. Those regions of the UBM layer 9 that are not covered by the photoresist 11 are removed, for example by means of etching (FIG. 3J). Then the photoresist 11 is removed, as shown in FIG. 3K.

Such an arrangement may be used, for example, to drive a display device.

1. An arrangement comprising a substrate, a capacitor, an interconnection layer and a contact structure, wherein
the capacitor comprises a first electrode and a second electrode and also an interposed dielectric,
the contact structure comprises a UBM (under-bump metallization) layer and a bump contact, and
the interconnection layer forms the first electrode of the capacitor and the UBM layer forms the second electrode of the capacitor.

2. An arrangement as claimed in claim 1, characterized in that the substrate comprises at least one component.

3. An arrangement as claimed in claim 2, characterized in that the capacitor is electrically coupled to the component.

4. An arrangement as claimed in claim 2, characterized in that the component is selected from the group comprising active components, passive components, and integrated circuits.

5. A display device comprising an arrangement with a substrate, a capacitor, an interconnection layer, and a contact structure, wherein
the capacitor comprises a first electrode and a second electrode and also an interposed dielectric,
the contact structure comprises a UBM (under-bump metallization) layer and a bump contact, and
the interconnection layer forms the first electrode of the capacitor and the UBM layer the second electrode of the capacitor.
